(19) United States
(12) Patent Application Publication
(10) Pub. No.: US 2022/0310684 A1
(43) Pub. Date: Sep. 29, 2022

(54) SOLID-STATE IMAGE SENSOR

(71) Applicant: Panasonic Intellectual Property Management Co., Ltd., Osaka (JP)

(72) Inventors: Yusuke SAKATA, Osaka (JP); Masaki TAMARU, Kyoto (JP); Mitsuyoshi MORI, Kyoto (JP)

(21) Appl. No.: 17/840,139

(22) Filed: Jun. 14, 2022

Related U.S. Application Data
(63) Continuation of application No. PCT/JP2020/046701, filed on Dec. 15, 2020.

(30) Foreign Application Priority Data
Dec. 20, 2019 (JP) 2019-230417

(51) Int. Cl. H01L 27/146

(52) U.S. Cl. CPC H01L 27/14605; H01L 27/14612; H01L 27/14638; H01L 27/14636

(57) ABSTRACT

A solid-state image sensor includes pixel cells each of which is formed in and above a semiconductor substrate and that are arranged in each of a first direction and a second direction intersecting the first direction to form a two-dimensional array. The pixel cells include a first pixel cell and a second pixel cell arranged in the second direction, and the pixel circuit of the first pixel cell and the pixel circuit of the second pixel cell are adjacent to each other in the second direction between the photodetection portion of the first pixel cell and the photodetection portion of the second pixel cell. Each of the first transistors of the first pixel cell shares a gate electrode with the first transistor of the second pixel cell that has the same function as the first transistor of the first pixel cell.

### CROSS REFERENCE TO RELATED APPLICATIONS

This is a continuation application of PCT International Application No. PCT/JP2020/046701 filed on Dec. 15, 2020, designating the United States of America, which is based on and claims priority of Japanese Patent Application No. 2019-230417 filed on Dec. 20, 2019. The entire disclosures of the above-identified applications, including the specifications, drawings and claims are incorporated herein by reference in their entirety.

### FIELD

The present disclosure relates to a solid-state image sensor including pixel cells.

### BACKGROUND

Japanese Unexamined Patent Application Publication No. 7-67043 (PTL1) discloses a solid-state imaging apparatus. The solid-state imaging apparatus includes, for each pixel, a photodetector having a photoelectric conversion function, a reset unit that repeatedly resets the photodetector, and a detector that detects information as to whether an incident photon has been detected between reset pulses that reset the photodetector. The solid-state imaging apparatus further includes, for each pixel, a count value storage unit that counts the detection pluses of the detector for a predetermined period and a readout unit that reads a count value from the count value storage unit for each predetermined period.

### CITATION LIST

### Patent Literature

PTL 1: Japanese Unexamined Patent Application Publication No. 7-67043

### SUMMARY

### Technical Problem

In the field of solid-state image sensors, such as the solid-state imaging apparatus disclosed in Japanese Unexamined Patent Application Publication No. 7-67043, in some cases, it is expected to achieve higher sensitivity and integration of, for example, pixel cells including photodetectors (photodetection portions). In particular, in the case in which the photodetectors are avalanche photodiodes (APD), an adequate isolation region to alleviate an electric field between photodetectors or between a photodetector and a pixel circuit including a detector is provided. The more pixel cells are miniaturized, the higher the area ratio of portions other than a photodetector to the size of a pixel cell, which makes it difficult to achieve both higher sensitivity and higher integration at the same time.

The present disclosure aims to provide a solid-state image sensor suitable to achieve higher sensitivity.

### Solution to Problem

A solid-state image sensor according to one aspect of the present disclosure includes a semiconductor substrate and pixel cells each of which is formed in and above the semiconductor substrate and that are arranged in each of a first direction and a second direction intersecting the first direction to form a two-dimensional array. The pixel cells each include a photodetection portion and a pixel circuit. The photodetection portion receives incident light and generates charge. The pixel circuit includes a charge holding portion for holding the charge generated in the photodetection portion, first transistors arranged in the first direction, and a second transistor that outputs, as a photodetection signal, a voltage corresponding to the charge held by the charge holding portion. The pixel cells include a first pixel cell and a second pixel cell arranged in the second direction, and the pixel circuit of the first pixel cell and the pixel circuit of the second pixel cell are adjacent to each other in the second direction between a first photodetection portion that is the photodetection portion of the first pixel cell and a second photodetection portion that is the photodetection portion of the second pixel cell. Each the first transistors of the first pixel cell shares a gate electrode with a corresponding one of the first transistors of the second pixel cell that has the same function as the first transistor of the first pixel cell.

### Advantageous Effects

The present disclosure can provide a solid-state image sensor suitable to achieve higher sensitivity.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates an arrangement of the pixel cells of a solid-state image sensor according to an embodiment.

FIG. 2 illustrates two pixel cells included in the solid-state image sensor according to the embodiment.

FIG. 3 illustrates a circuit configuration of a pixel circuit.

FIG. 4 is an enlarged figure of arrangements of the transistors of pixel circuits.

FIG. 5 is a cross-sectional view of the solid-state image sensor taken along the line V-V in FIG. 4.

FIG. 6 illustrates two pixel cells included in a solid-state image sensor according to Variation 1.

FIG. 7 illustrates two pixel cells included in a solid-state image sensor according to Variation 2.

FIG. 8 illustrates a circuit configuration of a pixel circuit according to Variation 2.

FIG. 9 illustrates two pixel cells included in a solid-state image sensor according to Variation 3.

FIG. 10 illustrates a circuit configuration of a pixel circuit according to Variation 3.

### DESCRIPTION OF EMBODIMENT

Hereinafter, an embodiment is described with reference to the drawings. It should be noted that the embodiment described below shows general or specific examples. The numerical values, shapes, materials, structural elements, arrangements and connections of the structural elements, and other details described in the embodiment below are mere examples and are not intended to limit the present disclosure. In addition, among the structural elements described in the embodiment below, the structural elements not included in the independent claim, which represents a superordinate concept, are described as optional structural elements.

It should be noted that the drawings are schematic diagrams and are not necessarily precisely drawn. Regarding, for instance, the rectangular portions in the drawings, corners may be changed into curved corners by ion implantation or heat treatment. In addition, if rectangular portions expand and overlap each other, the impurity concentrations of the rectangular portions are added up, which may create an impurity concentration portion not described in the embodiment below. In particular, a low-impurity-concentration portion is susceptible to its surrounding portion and likely to shrink, which may lead to a higher impurity concentration and partial inversion of the conductivity type. In the drawings, substantially the same elements are assigned the same reference symbol, and overlapping explanations may be omitted or simplified.

In addition, the drawings used to describe the embodiment below may include coordinate axes. A z-axis direction in the coordinate axes corresponds to, for example, a vertical direction. The positive side of the z-axis is expressed as the upper side (above) or the front side, and the negative side of the z-axis is expressed as the lower side (below) or the back side. In other words, the z-axis direction is a direction perpendicular to the top or bottom of a semiconductor substrate, that is, a thickness direction of the semiconductor substrate. The z-axis direction is also expressed as a depth direction. In this case, the positive side of the z-axis corresponds to shallow depths in the depth direction, and the negative side of the z-axis corresponds to deep depths in the depth direction.

In addition, the x-axis direction is orthogonal to the y-axis direction on a plane perpendicular to the z-axis direction. The x-axis direction is expressed as a lateral direction, a row direction, or a first direction whereas the y-axis direction is expressed as a longitudinal direction, a column direction, or a second direction. In the embodiment below, the expression in plan view means that an object is viewed in the z-axis direction. In addition, the embodiment below in the present disclosure does not exclude a structure where the p- and n-types are inverted.

### [Overview]

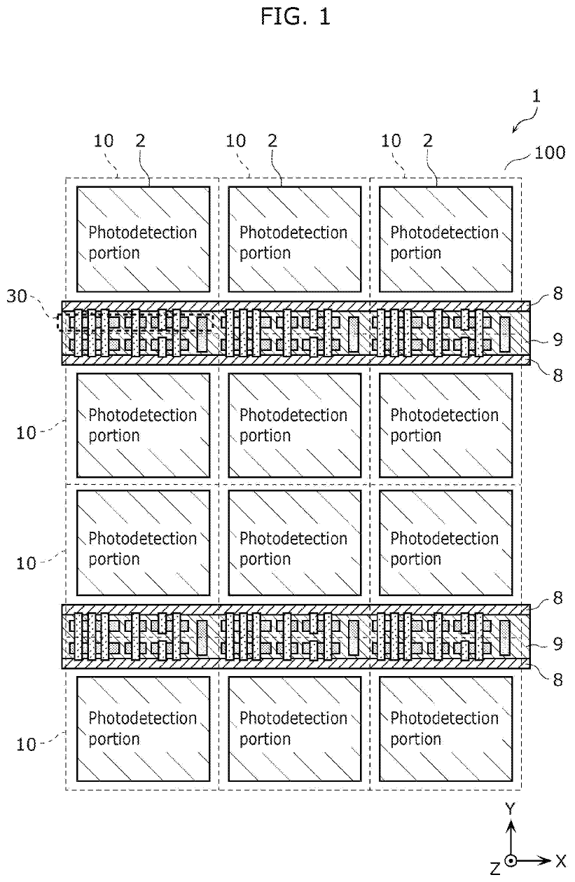

An overview of a solid-state image sensor according to an embodiment is described hereinafter. FIG. 1 illustrates an arrangement of the pixel cells of a solid-state image sensor according to an embodiment.

Solid-state image sensor 1 according to the embodiment is used in a range-finding system that obtains a range image of a target space by, for example, the time of flight (TOF) method. The range-finding system includes, for example, a light wave emitting module for emitting pulsed light, a light wave receiving module for receiving the pulsed light (reflected light) that had been emitted by the light wave emitting module and was reflected off a target object, and a processing unit that calculates the distance to the target object on the basis of the reflected light received by the light wave receiving module. The processing unit can calculate the distance to the target object from the time at which the light wave emitting module emitted the pulsed light and the time at which the light wave receiving module received the reflected light.

It is preferable that the pulsed light emitted by the light wave emitting module be monochromatic light and have a relatively narrow pulse width and a relatively high peak intensity. In addition, considering that the range-finding system is used in, for example, a town, it is preferable that the wavelength of the pulsed light be within a near-infrared wavelength range in which human visibility is low and that is insusceptible to ambient light that comes from sunlight.

Such a range-finding system can be used in, for example, an object recognition system that is included in an automobile and detects an obstacle, a surveillance camera for detecting, for example, an object (person), or a security camera. Solid-state image sensor 1 is used in, for example, the light wave receiving module of the above range-finding system.

As illustrated in FIG. 1, solid-state Image sensor 1 includes semiconductor substrate 100 and pixel cells 10. Pixel cells 10 are each formed in and above semiconductor substrate 100. Pixel cells 10 are arranged in a two-dimensional array near the top of semiconductor substrate 100.

More specifically, pixel cell groups each including pixel cells 10 arranged in the x-axis direction (a horizontal direction in FIG. 1) (hereinafter also referred to as the first direction) are arranged in the y-axis direction (a vertical direction in FIG. 1) (hereinafter also referred to as the second direction) intersecting the x-axis direction. It should be noted that for explanatory convenience, FIG. 1 does not illustrate elements such as wire 60 that connects photodetection portion 2 and pixel circuit 30 to each other and wire 61 that connects transistors included in pixel circuit 30 to each other.

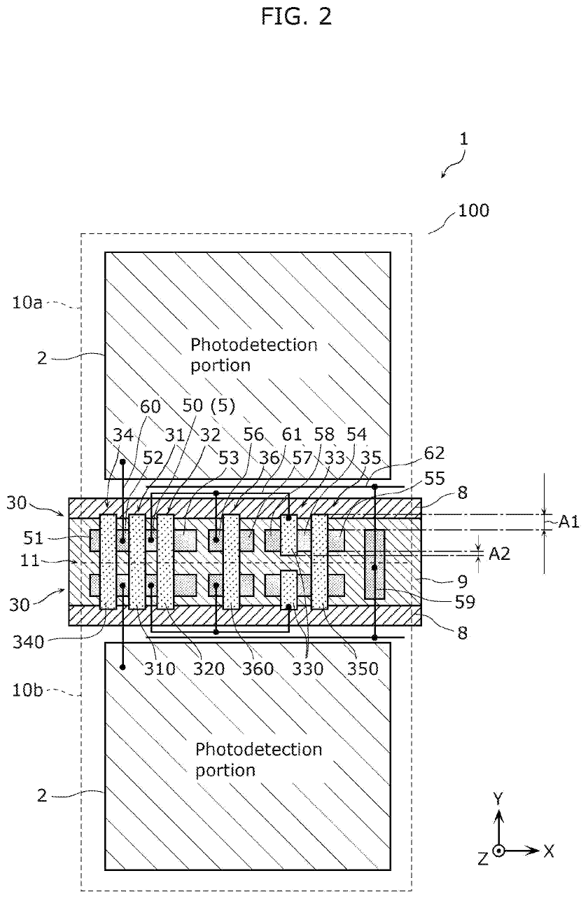

FIG. 2 illustrates two pixel cells 10 among pixel cells 10. In FIG. 2, two pixel cells 10 are referred to as first pixel cell 10a and second pixel cell 10b. As illustrated in FIG. 2, first pixel cell 10a and second pixel cell 10b each have photodetection portion 2 and pixel circuit 30.

Photodetection portion 2 is formed in semiconductor substrate 100. Photodetection portion 2 is a photoelectric conversion portion that receives incident light and generates charge. The photoelectric conversion portion is, for example, an avalanche photodiode. However, the photoelectric conversion portion may be a typical photodiode. If the photoelectric conversion portion is an avalanche photodiode, photodetection portion 2 includes a multiplication region where avalanche multiplication of charge generated by reception of incident light takes place.

Pixel circuit 30 is used to output a photodetection signal corresponding to the charge generated in photodetection portion 2. Pixel circuit 30 includes transistors. Specifically, the transistors are transfer transistor 31, first reset transistor 32, amplification transistor 33, selection transistor 35, second reset transistor 34, and count transistor 36. Among the transistors, transfer transistor 31, first reset transistor 32, selection transistor 35, second reset transistor 34, and count transistor 36 are also referred to as first transistors, and amplification transistor 33 is also referred to as a second transistor.

Each of the transistors is formed in and above semiconductor substrate 100. The gate electrodes of the transistors are arranged in the first direction (a horizontal direction in FIG. 2). The arrangement of the transistors of first pixel cell 10a (the order in which the transistors are arranged) from left to right is the same as that of the transistors of second pixel cell 10b from left to right. That is, in plan view, the configuration of first pixel cell 10a and second pixel cell 10b has horizontal symmetry. Photodetection portion 2 of first pixel cell 10a is adjacent to photodetection portion 2 of pixel cell 10 disposed on the opposite side from second pixel cell 10b and is not adjacent to pixel circuit 30 of pixel cell 10 on the opposite side from second pixel cell 10b (see FIG. 1). The same applies to second pixel cell 10b.

In such an arrangement of solid-state image sensor 1, the number of connection boundaries between pixel circuits 30 and photodetection portions 2 is fewer compared with an arrangement in which photodetection portion 2 alternates with pixel circuit 30. Thus, solid-state image sensor 1 has a smaller total area of isolation regions each provided between pixel circuit 30 and photodetection portion 2, which can increase the area ratio of photodetection portion 2 without changing a pixel size. That is, higher sensitivity is readily achieved in solid-state image sensor 1.

Pixel circuit 30 includes charge holding portion 5. Charge holding portion 5 is connected to photodetection portion 2 via transfer transistor 31 by wire 60. Charge holding portion 5 holds (accumulates) charge generated in photodetection portion 2. In addition, charge holding portion 5 is also connected to gate electrode 330 of amplification transistor 33 by wire 61.

Here, as described above, the transistors include the first transistors and the second transistor. Specifically, the first transistors are transfer transistor 31, first reset transistor 32, selection transistor 35, second reset transistor 34, and count transistor 36. Specifically, the second transistor is amplification transistor 33.

Each of the first transistors of first pixel cell 10a shares the gate electrode with the first transistor of second pixel cell 10b that has the same function as the first transistor of first pixel cell 10a. Specifically, the gate electrodes of the first transistors are gate electrodes 310, 320, 340, 350, and 360. Each of gate electrodes 310, 320, 340, 350, and 360 linearly extends in the second direction across boundary 11 between first pixel cell 10a and second pixel cell 10b.

Such sharing of the gate electrodes in pixel circuits 30 by first pixel cell 10a and second pixel cell 10b leads to a decrease in the number of wires that pass through effective pixels to apply voltages to the gate electrodes. Thus, solid-state image sensor 1 can suppress light to which the effective pixels have been exposed from reflecting off the wires. That is, higher sensitivity is readily achieved in solid-state image sensor 1.

In addition, in plan view, the gate electrodes are used as masks when forming the diffusion regions of the transistors (diffusion regions 50 to 58 in FIG. 2), and the lengths of the gate electrodes in the second direction are set to lengths at which manufacturing variations between the transistors can be suppressed.

Here, first pixel cell 10a and second pixel cell 10b do not share gate electrode 330 of amplification transistor 33, which means that gate electrodes 330 serve as individual gate electrodes to each of which an independent voltage is applied. In solid-state image sensor 1, protrusion length A2 of gate electrode 330 is less than protrusion length A1 of the gate electrodes of the other transistors. This is to decrease the width of pixel circuit 30 in the second direction and the distance between pixel circuits 30 of first pixel cell 10a and second pixel cell 10b.

Protrusion length A1 is set to a length at which manufacturing variations between the transistors can be sufficiently suppressed. Protrusion length A2 is set to a length at which characteristic variations between amplification transistors 33 can be canceled in a correlated double sampling (CDS) circuit, which is a subsequent circuit. Such lengths are determined through experience or experiments. Thus, degradation in image quality falls within the permissible range.

Under the condition that protrusion length A2 is less than protrusion length A1 as described above, gate electrodes 330 of amplification transistors 33 of first pixel cell 10a and second pixel cell 10b are a certain distance apart from each other. Thus, it is possible to decrease the distance from diffusion regions 50 to 58 to boundary 11 while suppressing parasitic capacitance between charge holding portions 5. Accordingly, it is possible to decrease the width of pixel circuit 30 in the second direction and increase the area ratio of photodetection portion 2. That is, higher sensitivity is readily achieved in solid-state image sensor 1.

### [Circuit Configuration]

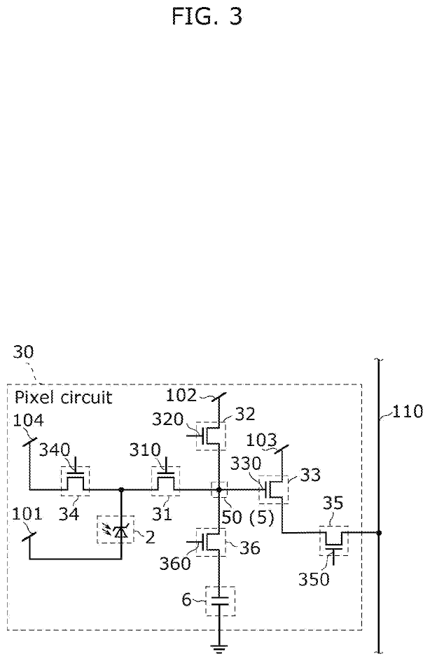

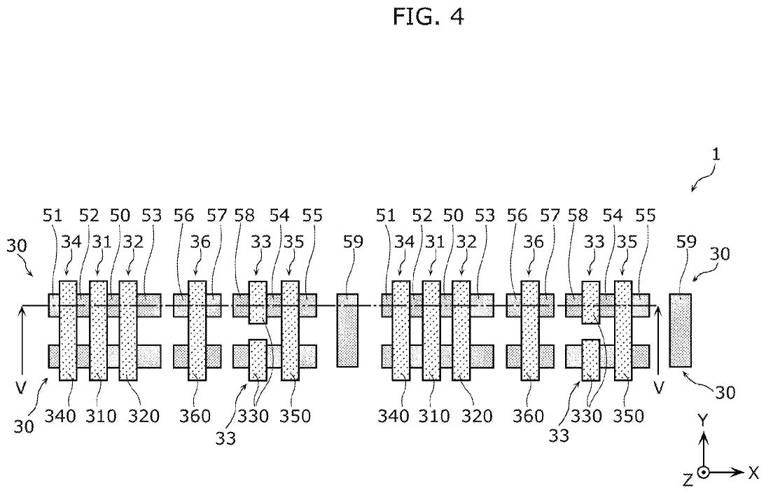

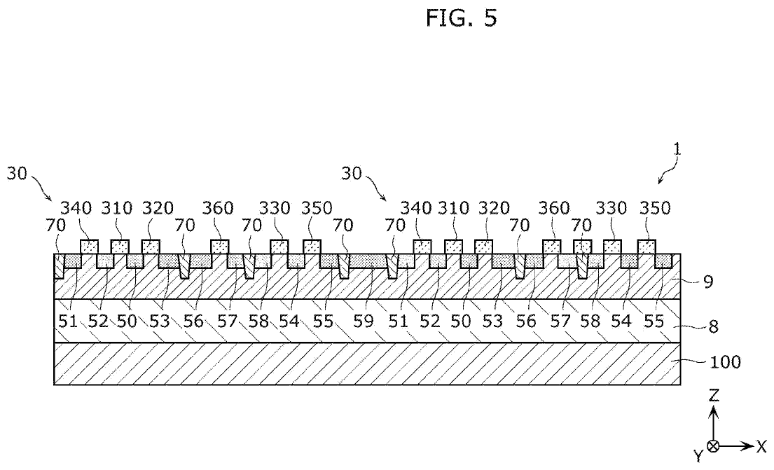

A circuit configuration of pixel circuit 30 is described in more detail with reference to FIGS. 3 to 5 as well as FIGS. 1 and 2. FIG. 3 illustrates a circuit configuration of pixel circuit 30. FIG. 4 is an enlarged figure of arrangements of the transistors of pixel circuits 30. FIG. 5 is a cross-sectional view of the solid-state image sensor taken along the line V-V in FIG. 4.

As illustrated in FIGS. 1 to 5, pixel circuit 30 includes transfer transistor 31, first reset transistor 32, amplification transistor 33, selection transistor 35, second reset transistor 34, count transistor 36, charge holding portion 5, and memory portion 6. FIG. 3 illustrates photodetection portion 2 in addition to pixel circuit 30.

Photodetection portion 2 is a photodiode formed in an upper portion of semiconductor substrate 100. The photodiode described here is an avalanche photodiode (hereinafter, also referred to as APD). Photodetection portion 2 includes, for example, an n-type diffusion region formed in p-type semiconductor substrate 100.

Photodetection portion 2 embodied as an APD has a first mode and a second mode as operation modes. When photodetection portion 2 receives light in a state in which a reverse bias voltage smaller than a breakdown voltage is applied, photodetection portion 2 collects, in the cathode of photodetection portion 2, charge whose amount is substantially proportional to the number of photons that cause photoelectric conversion (first mode). In addition, when photodetection portion 2 receives light in a state in which a reverse bias voltage greater than or equal to the breakdown voltage is applied, photoelectric conversion by a photon causes photodetection portion 2 to collect a saturation amount of charge in the cathode (second mode). The operation mode of photodetection portion 2 can be changed by changing the potential of bias electrode 101 connected to the anode of photodetection portion 2.

Charge holding portion 5 holds the charge generated in photodetection portion 2. Diffusion region 50 described here corresponds to a floating diffusion (FD) portion.

Transfer transistor 31 includes diffusion regions 50 and 52 formed in semiconductor substrate 100 and gate electrode 310. Diffusion region 52 of transfer transistor 31 is connected to the cathode of photodetection portion 2 by wire 60. Wire 60 is, for example, a metal wire. Diffusion region 50 is shared with first reset transistor 32 and also function as charge holding portion 5.

When a voltage is applied to gate electrode 310 and transfer transistor 31 is switched on, transfer transistor 31 transfers the charge collected in the cathode of photodetection portion 2 to diffusion region 50.

First reset transistor 32 includes diffusion regions 50 and 53 formed in semiconductor substrate 100 and gate electrode 320. Diffusion region 53 of first reset transistor 32 is connected to first reset drain electrode 102. Diffusion region 50 is shared with transfer transistor 31 and also functions as charge holding portion 5.

When a voltage is applied to gate electrode 320 and first reset transistor 32 is switched on, the charge accumulated in diffusion region 50 is discharged into first reset drain electrode 102. That is, first reset transistor 32 resets diffusion region 50 to discharge the charge accumulated in diffusion region 50.

Amplification transistor 33 includes diffusion regions 54 and 58 formed in semiconductor substrate 100 and gate electrode 330. Diffusion region 58 of amplification transistor 33 is connected to amplification electrode 103. Diffusion region 54 is shared with selection transistor 35. Gate electrode 330 of amplification transistor 33 is connected to diffusion regions 50 and 56 by wire 61. Wire 61 is, for example, a metal wire.

Amplification transistor 33 outputs a voltage corresponding to the amount of the charge accumulated in diffusion region 50. The voltage output by amplification transistor 33 corresponds to a photodetection signal output by pixel cell 10 (a photodetection signal corresponding to the charge generated in photodetection portion 2).

Selection transistor 35 includes diffusion regions 54 and 55 formed in semiconductor substrate 100 and gate electrode 350.

Diffusion region 55 of selection transistor 35 is connected to signal line 110. Diffusion region 54 is shared with amplification transistor 33.

Only when a voltage is applied to gate electrode 350 and selection transistor 35 is switched on, selection transistor 35 causes pixel cell 10 to output, to signal line 110, the voltage (the photodetection signal) output by amplification transistor 33. Second reset transistor 34 includes diffusion regions 51 and 52 formed in semiconductor substrate 100 and gate electrode 340.

Diffusion region 51 of second reset transistor 34 is connected to second reset drain electrode 104. Diffusion region 52 of second reset transistor 34 is connected to the cathode of photodetection portion 2 by wire 60.

When a voltage is applied to gate electrode 340 and second reset transistor 34 is switched on, the charge accumulated in the cathode of photodetection portion 2 is discharged into second reset drain electrode 104. That is, second reset transistor 34 resets the cathode of photodetection portion 2 to discharge the charge accumulated in the cathode.

Memory portion 6 is embodied as, for example, a capacitor that accumulates charge. For instance, memory portion 6 has a layered structure including a pair of electrodes and an insulation layer interposed between the electrodes. Memory portion 6 may have a layered structure including an electrode, a semiconductor layer, and an insulation layer interposed between the electrode and the semiconductor layer. For instance, memory portion 6 is disposed above semiconductor substrate 100 with an insulation layer interposed between memory portion 6 and semiconductor substrate 100. In addition, memory portion 6 may have a layered structure including two wire layers and an insulation layer interposed between the two wire layers.

Count transistor 36 includes diffusion regions 56 and 57 formed in semiconductor substrate 100 and gate electrode 360.

Diffusion region 56 of count transistor 36 is connected to diffusion region 50 and gate electrode 330 by wire 61. Diffusion region 57 of count transistor 36 is connected to memory portion 6.

When a voltage is not applied to gate electrode 360 and count transistor 36 is in an off-state, count transistor 36 inhibits the charge from traveling between diffusion region 50 and memory portion 6. When a voltage is applied to gate electrode 360 and count transistor 36 is switched on, count transistor 36 causes the charge to travel between diffusion region 50 and memory portion 6.

A circuit configuration of pixel circuit 30 is described above. It should be noted that a single electrode (the same electrode) may serve as first reset drain electrode 102 and second reset drain electrode 104. In addition, a single electrode (the same electrode) may serve as amplification electrode 103 and at least one of second reset drain electrode 104 and first reset drain electrode 102. In solid-state image sensor 1, a single electrode (the same electrode) serves as first reset drain electrode 102 and second reset drain electrode 104 (the two electrodes are connected to each other), and the same power supply is connected to first reset drain electrode 102 and second reset drain electrode 104.

### [Operation]

Operation of solid-state image sensor 1 is described hereinafter. Solid-state image sensor 1 includes a controller (control circuit) for controlling operation of pixel cells 10. The controller controls pixel cell 10 by controlling, for example, a voltage applied to bias electrode 101 or voltages applied to the respective gate electrodes of the first transistors included in pixel circuit 30.

The controller of solid-state image sensor 1 has a first photodetection mode and a second photodetection mode as operation modes. In the first photodetection mode, the controller causes photodetection portion 2 of pixel cell 10 to operate in the first mode. Specifically, the controller adjusts a voltage applied to bias electrode 101 to cause photodetection portion 2 to operate in the first mode.

In the second photodetection mode, the controller causes photodetection portion 2 of pixel cell 10 to operate in the second mode. Specifically, the controller adjusts a voltage applied to bias electrode 101 to cause photodetection portion 2 to operate in the second mode. Here, the controller adjusts the voltage so that a potential difference between the anode and cathode of photodetection portion 2 is large compared with when photodetection portion 2 operates in the first mode. The second photodetection mode is more suitable to detect weak light than the first photodetection mode.

In the first photodetection mode, solid-state image sensor 1 operates in the following manner. First, the controller of solid-state image sensor 1 switches on first reset transistor 32, second reset transistor 34, and count transistor 36 to initialize the cathode of photodetection portion 2, charge holding portion 5 (diffusion region 50), and memory portion 6 (discharge the accumulated charge). It should be noted that at this time, transfer transistor 31 is switched off.

Next, the controller switches off first reset transistor 32, second reset transistor 34, and count transistor 36. This state is the exposure state of pixel cell 10. When receiving light in the exposure state, photodetection portion 2 collects, in the cathode, charge whose amount is substantially proportional to the number of photons that cause photoelectric conversion.

Here, the potential of second reset transistor 34 when an off level (off voltage) is applied to second reset transistor 34 is lower than that of transfer transistor 31 when an off level (off voltage) is applied to transfer transistor 31. Thus, when the amount of the charge collected in the cathode of photodetection portion 2 reaches the saturation level of the cathode, a portion of the charge that has exceeded the saturation level overflows into second reset drain electrode 104 across the potential barrier of second reset transistor 34.

Then, the controller switches on first reset transistor 32 to initialize charge holding portion 5. The controller switches on transfer transistor 31 to connect the cathode of photodetection portion 2 and charge holding portion 5 to each other. Thus, the charge collected in the cathode of photodetection portion 2 is transferred to and accumulated in charge holding portion 5 (diffusion region 50).

Finally, the charge accumulated in charge holding portion 5 is converted into a photodetection signal corresponding to the amount of the accumulated charge, by amplification transistor 33 including gate electrode 330 connected to charge holding portion 5. By switching on selection transistor 35 of target pixel cell 10 among pixel cells 10, the controller causes target pixel cell 10 to output the photodetection signal to signal line 110.

In the second photodetection mode, solid-state image sensor 1 operates in the following manner. The controller splits a predetermined measurement period into exposure periods. The controller counts photons detected by photodetection portion 2 during the measurement period, according to whether photoelectric conversion has been performed during the exposure process for each exposure period. The controller causes pixel cell 10 to operate in the following manner.

First, at the beginning of the measurement period, the controller switches on first reset transistor 32, second reset transistor 34, and count transistor 36 to initialize (reset) the cathode of photodetection portion 2, charge holding portion 5 (diffusion region 50), and memory portion 6. It should be noted that at this time, transfer transistor 31 is switched off.

Next, at the beginning of the exposure period of each exposure process, the controller switches off first reset transistor 32, second reset transistor 34, and count transistor 36 and switches on transfer transistor 31. This state is the exposure state of pixel cell 10. When photodetection portion 2 receives light in the exposure state, photoelectric conversion by a photon causes photodetection portion 2 to collect, in the cathode, charge to the extent that charge holding portion 5 is saturated (a saturation amount of charge). It should be noted that as described above, the potential of second reset transistor 34 when an off level (off voltage) is applied to second reset transistor 34 is lower than that of transfer transistor 31 when an off level (off voltage) is applied to transfer transistor 31. Thus, a portion of the collected charge that has exceeded the saturation level of the cathode of photodetection portion 2 overflows into second reset drain electrode 104 across the potential barrier of second reset transistor 34. Accordingly, the amount of the charge accumulated in the cathode of photodetection portion 2 in the second mode (the amount of charge accumulated in the cathode by photoelectric conversion caused by a photon) is roughly the same every time (the amount of charge corresponding to the saturation level of the cathode).

Then, the controller switches off transfer transistor 31. Thus, charge holding portion 5 holds charge, which is a portion of the charge collected in the cathode of photodetection portion 2 and distributed to charge holding portion 5.

Finally, the controller switches on count transistor 36 and redistributes the charge accumulated in charge holding portion 5 to charge holding portion 5 and memory portion 6. That is, the controller transfers (a portion of) the charge accumulated in charge holding portion 5 to memory portion 6. Thus, a portion of the charge generated by photodetection portion 2 performing photoelectric conversion is transferred to memory portion 6, which increases the amount of charge of memory portion 6.

Meanwhile, if photodetection portion 2 does not receive light during the exposure period, photodetection portion 2 will not perform photoelectric conversion or collect charge in the cathode. Thus, even if the controller switches on transfer transistor 31, charge will not be transferred from the cathode of photodetection portion 2 to charge holding portion 5. That is, even if count transistor 36 is switched on later, the amount of charge of memory portion 6 will not increase.

The controller repeats the above operation the number of times of exposure processes. Thus, charge whose amount corresponds to the number of times of exposure processes during which photodetection portion 2 received light, among exposure processes included in one measurement period is accumulated in memory portion 6.

It should be noted that in practice, if photodetection portion 2 receives light during the first exposure process, charge is already accumulated in memory portion 6 when the second and subsequent exposure processes are performed. Thus, the amount of charge of memory portion 6 that increases through each of the second and subsequent exposure processes differs from the amount of charge accumulated during the first exposure process. In addition, in the second and subsequent exposure processes, first reset transistor 32 does not necessarily have to be switched off at the beginning of the exposure process. However, since to describe these respects is not the main objective of the present disclosure, detailed explanations are omitted.

At the end of the measurement period (after all the exposure processes are complete), the controller switches on count transistor 36 and connects memory portion 6 and charge holding portion 5 to each other to distribute the charge accumulated in memory portion 6 to memory portion 6 and charge holding portion 5. By using amplification transistor 33 including gate electrode 330 connected to charge holding portion 5, the charge distributed from memory portion 6 to charge holding portion 5 is converted into a photodetection signal corresponding to the amount of the charge (that is, corresponding to the number of times of the exposure processes during which photodetection portion 2 received light). The controller switches on selection transistor 35 of target pixel cell 10 among pixel cells 10 to cause target pixel cell 10 to output the photodetection signal to signal line 110.

The CDS circuit then reads the photodetection signal output by signal line 110. The CDS circuit outputs, from a CDS output node, a signal corresponding to a difference between potentials at given two different times in corresponding signal line 110, that is, a difference between a potential when a signal output operation is performed (a potential when charge holding portion 5 includes signal charge) and a potential when a reset operation is performed (a potential after the charge is discharged from charge holding portion 5 by using first reset transistor 32).

### [Layout of Pixel Cells]

A layout of pixel cells 10 in solid-state image sensor 1 is described with reference to FIGS. 1, 2, 4, and 5.

As illustrated in FIG. 1, pixel cells 10 are each formed in and above semiconductor substrate 100 and are arranged in a two-dimensional array. Semiconductor substrate 100 is, for example, a p-type silicon substrate. N-type well region 8 is formed in semiconductor substrate 100 so that a longitudinal direction of n-type well region 8 is identical to the first direction (the horizontal direction in FIG. 1). P-type well region 9 is formed in the longitudinal direction of n-type well region 8 (first direction) inside n-type well region 8.

In plan view, pixel circuits 30 are formed in p-type well region 9. Photodetection portion 2 is formed above a p-type region of semiconductor substrate 100 outside n-type well region 8.

Pixel cells 10 (three pixel cells in FIG. 1) (hereinafter, also referred to as a first group of pixel cells) are arranged along one side of p-type well region 9 in a longitudinal direction of p-type well region 9. In addition, pixel cells 10 (three pixel cells in FIG. 1) (hereinafter, also referred to as a second group of pixel cells) are arranged along the other side of p-type well region 9 in the longitudinal direction of p-type well region 9. In plan view, pixel circuits 30 of pixel cells 10 included in the first group of pixel cells and pixel circuits 30 of pixel cells 10 included in the second group of pixel cells are formed in p-type well region 9.

It should be noted that in the example illustrated in FIG. 1, pixel circuits 30 of six pixel cells 10 of the first group of pixel cells and the second group of pixel cells are formed in one p-type well region 9. However, this is not the only example. The first group of pixel cells may include two or less pixel cells 10 or four or more pixel cells 10. Likewise, the second group of pixel cells may include two or less pixel cells 10 or four or more pixel cells 10. The number of pixel cells 10 included in the second group of pixel cells may be identical to or different from that of pixel cells 10 included in the first group of pixel cells.

In the example illustrated in FIG. 1, pixel cells 10 included in the first group of pixel cells have the same shape and size, and pixel cells 10 included in the second group of pixel cells have the same shape and size. Furthermore, pixel cells 10 included in the first group of pixel cells and pixel cells 10 included in the second group of pixel cells have the same shape and size.

If pixel cells 10 have the same shape and size, it is possible to make wires 60 connected to pixel cells 10 have substantially the same shape and make wires 61 connected to pixel cells 10 have substantially the same shape. That is, it is possible to cause wires 60 to have a uniform length and wires 61 to have a uniform length, which enables wires 60 to have uniform parasitic resistance and capacitance and wires 61 to have uniform parasitic resistance and capacitance. In other words, it is possible to decrease characteristic variations between pixel cells 10.

In addition, regarding two pixel cells 10 adjacent to each other in the second direction (a lateral direction of p-type well region 9, the vertical direction in FIG. 1) among pixel cells 10 in plan view, two photodetection portions 2 are adjacent to each other, or two pixel circuits 30 are adjacent to each other.

### [Layout of Structural Elements of Pixel Circuit]

A layout of the structural elements of pixel circuit 30 is described hereinafter. As illustrated in FIGS. 2, 4, and 5, the structural elements of pixel circuit 30 are arranged in a region whose longitudinal direction is identical to the first direction. In the region, second reset transistor 34, transfer transistor 31, first reset transistor 32, count transistor 36, amplification transistor 33, and selection transistor 35 are arranged in the order named in the first direction from the left (the negative side of the x-axis). More specifically, diffusion regions 50 to 59 are arranged in the first direction, and gate electrodes 310 to 360 are arranged in the first direction.

Diffusion regions 50 to 58 are n-type diffusion regions formed in p-type well region 9. As illustrated in FIGS. 2, 4, and 5, diffusion regions 51, 52, 50, 53, 56, 57, 58, 54, and 55 are arranged in the order named in the first direction from the left in the figures.

Diffusion region 59 is a p-type diffusion region formed in p-type well region 9. Diffusion region 59 is connected, via well wire 62, to a power supply (typically a ground power supply) for fixing the voltage of p-type well region 9 in pixel cells 10. That is, diffusion region 59 servers as a well contact. Well wire 62 is, for example, a metal wire. N-type well region 8 is connected to a power supply (typically, a voltage of around 1 V to 5 V) that applies a reverse bias voltage between n-type well region 8 and p-type well region 9.

A longitudinal direction of each of gate electrodes 310 to 360 is identical to the second direction. In plan view, each of gate electrodes 310 to 360 is linear (has a straight-line shape). However, each of gate electrodes 310 to 360 may be L-shaped or have other shapes. Gate electrodes 340, 310, 320, 360, 330, and 350 are arranged in the order named in the first direction from the left in the figures.

Each of gate electrodes 310 to 360 is formed above semiconductor substrate 100 with a gate insulation film (not illustrated) including oxide silicon interposed between the gate electrode and semiconductor substrate 100. Each of gate electrodes 310 to 360 is formed above semiconductor substrate 100 so as to extend between ends of two diffusion regions adjacent to each other in the first direction. The transistors of pixel circuit 30 each include two adjacent diffusion regions, a gate electrode extending between the two adjacent diffusion regions, and a gate Insulation film.

It should be noted that as illustrated in FIG. 5, diffusion regions which are not supposed to be electrically connected to each other are isolated from each other by an insulator, such as shallow trench isolation (STI) 70. The diffusion regions which are not supposed to be electrically connected to each other may be isolated from each other by a diffusion region having a different conductivity type. In addition, in a portion in which two adjacent gate electrodes are far apart from each other, a dummy component made of the same material as the gate electrodes may be disposed, for example.

### [Configuration Having Horizontal Symmetry and Effects Thereof]

As illustrated in FIG. 2, pixel cells 10 include first pixel cell 10a and second pixel cell 10b arranged in the second direction, and when one of first pixel cell 10a and second pixel cell 10b is inverted, the one has the same layout as the other. That is, first pixel cell 10a and second pixel cell 10b are symmetrical to each other with respect to the axis of symmetry, which is boundary 11 in this case.

Pixel circuit 30 of first pixel cell 10a and pixel circuit 30 of second pixel cell 10b are adjacent to each other in the second direction between a first photodetection portion that is photodetection portion 2 of first pixel cell 10a and a second photodetection portion that is photodetection portion 2 of second pixel cell 10b.

Thus, solid-state image sensor 1 has fewer boundaries between pixel circuits 30 and photodetection portions 2, compared with an arrangement in which pixel circuit 30 alternates with photodetection portion 2 in the second direction (hereinafter, the arrangement is also referred to as a comparison example). In the comparison example, for every two rows, there are four boundaries between pixel circuits 30 and photodetection portions 2. In solid-state image sensor 1, for every two rows, there are two boundaries between pixel circuits 30 and photodetection portions 2, and there is one boundary between two photodetection portions 2, which is not found in the comparison example. In solid-state image sensor 1, the number of boundaries for which isolation regions should be provided is one fewer compared with the comparison example. It should be noted that there is low necessity of providing an isolation region for the boundary between pixel circuits 30.

Accordingly, solid-state image sensor 1 has a smaller total area for isolation regions, which makes it possible to increase the area ratio of each photodetection portion 2. That is, higher sensitivity is readily archived in solid-state image sensor 1.

### [Sharing of Gate Electrodes and Effects Thereof]

In addition, as illustrated in FIG. 2, the arrangement of the transistors of first pixel cell 10a in the first direction is identical to that of the transistors of second pixel cell 10b in the first direction. Each of the first transistors of first pixel cell 10a (the five transistors, i.e., the transistors except for amplification transistor 33) shares the gate electrode with the first transistor of second pixel cell 10b that has the same function as the first transistor of first pixel cell 10a. Each of the gate electrodes extends across boundary 11 between first pixel cell 10a and second pixel cell 10b. A voltage common to first pixel cell 10a and second pixel cell 10b is applied to the gate electrode.

Thus, in the entirety of solid-state image sensor 1, pixels for two rows can be driven concurrently by disposing five gate electrode wires per two rows. Thus, while photodetection signals from two pixels adjacent to each other in the second direction are retained for each pixel, concurrent light exposure and readout for two rows are made possible, which can increase the frame rate. In addition, the degree of layout freedom can be improved by reducing the number of the gate electrode wires. By disposing the gate electrode wires near boundary 11, it is possible to suppress incident light having a large incident angle from reflecting off the gate electrode wires. That is, sharing of the gate electrodes also leads to higher optical sensitivity.

In addition, the longitudinal direction of each of the gate electrodes of the first transistors (the five transistors, i.e., the transistors except for amplification transistor 33) is identical to the second direction. Thus, the length of a protruded portion of the gate electrode extending between the diffusion regions of pixel circuits adjacent to each other in the second direction, across boundary 11 is automatically sufficiently longer than protrusion length A1 at which manufacturing variations between the transistors can be sufficiently suppressed. That is, sharing of the gate electrodes suppresses variations in the threshold voltages (Vt) of the first transistors.

It should be noted that first pixel cell 10a and second pixel cell 10b do not share the gate electrode of amplification transistor 33. That is, the second transistor (that is, amplification transistor) of first pixel cell 10a does not share the gate electrode with the second transistor of second pixel cell 10b. An independent voltage is applied to each of the gate electrode of amplification transistor 33 of first pixel cell 10a and the gate electrode of amplification transistor 33 of second pixel cell 10b.

### [Adjustment of Protrusion Lengths and Effects Thereof]

As illustrated in FIG. 2, in solid-state image sensor 1, protrusion length A2 of gate electrode 330 is less than protrusion length A1 of the gate electrodes of the other transistors. Protrusion length A1 is set to a length at which manufacturing variations between the transistors can be sufficiently suppressed. Protrusion length A2 is set to a length at which characteristic variations between amplification transistors 33 can be canceled in the subsequent CDS circuit. Such lengths are determined through experience or experiments. Thus, degradation in image quality falls within the permissible range.

In addition, by separating gate electrodes 330 of first pixel cell 10a and second pixel cell 10b from each other by a certain distance, it is possible to dispose the diffusion regions near boundary 11 while suppressing occurrence of parasitic capacitance between charge holding portions 5 of first pixel cell 10a and second pixel cell 10b. That is, it is possible to decrease the width in second direction of a region where pixel circuit 30 is disposed. Accordingly, by increasing the area ratio of photodetection portion 2, higher sensitivity is readily achieved in solid-state image sensor 1.

If for instance protrusion length A1 at which variations in the threshold voltages (Vt) of the first transistors can be suppressed is 0.1 μm, and protrusion length A3 (not illustrated) between gate electrodes 330, at which parasitic capacitance between charge holding portions 5 can be suppressed is 0.1 μm, the diffusion regions of amplification transistor 33 of first pixel cell 10a and the diffusion regions of amplification transistor 33 of second pixel cell 10b are A1×2+A3=0.3 μm apart from each other in the second direction.

In contrast, if protrusion length A2 at which the subsequent CDS circuit can cancel variations in the threshold voltages (Vt) of amplification transistors 33 is 0.05 μm, the diffusion regions of amplification transistor 33 of first pixel cell 10a and the diffusion regions of amplification transistor 33 of second pixel cell 10b should be A2×2+A3=0.2 μm apart from each other in the second direction. Thus, if protrusion length A2 is employed, it is possible to increase the length of photodetection portion 2 by 0.1 μm in the second direction compared with when protrusion length A1 is employed, which can lead to an increase in the area ratio of photodetection portion 2. In this manner, higher sensitivity is achieved.

### [Increase in Parasitic Capacitance and Effects Thereof]

When solid-state image sensor 1 is used in the second photodetection mode, the amount of charge when light is detected is equivalent to the amount of charge at the saturation levels of photodetection portion 2 and charge holding portion 5 (a saturation charge amount). The reason for this is described below. When an electron-hole pair to be a photodetection trigger is generated in photodetection portion 2, a positive feedback is created in which the first generated electron-hole pair generates a new electron-hole pair, which further generates an electron-hole pair. When a certain amount of charge is accumulated in photodetection portion 2 and charge holding portion 5, the potential of the cathode of photodetection portion 2 decreases to the negative side, which makes the electric field fall below an electric field necessary for an electron-hole pair to continue to generate a new electron-hole pair. Thus, generation of an electron-hole pair stops in this state. The decreased amount of the potential of the cathode of photodetection portion 2 is proportional to the amount of generated charge and inversely proportional to the total amount of parasitic capacitance in photodetection portion 2 and parasitic capacitance in charge holding portion 5. That is, even if the parasitic capacitance in charge holding portion 5 increases, the amount of charge accumulated in charge holding portion 5 increases eventually. The generation of an electron-hole pair stops at a similar voltage regardless of the magnitude of the parasitic capacitance in charge holding portion 5.

Thus, as long as solid-state image sensor 1 is used in the second photodetection mode, wire 61 connected to charge holding portion 5 does not necessarily have to be designed to have a short length to decrease parasitic capacitance. In addition, if charge holding portion 5 has large parasitic capacitance, the amount of charge transferrable to memory portion 6 when count transistor 36 is switched on increases. Thus, as a voltage change in memory portion 6 per count increases, it is possible to adjust the amount of voltage change per count to be higher than a noise level.

Here, wire 61 connected to charge holding portion 5 is also considered as a portion of charge holding portion 5. That is, it can be said that charge holding portion 5 includes wire 61. The parasitic capacitance in charge holding portion 5 can be increased by increasing parasitic capacitance between wire 61 and a power supply line for use in applying a fixed voltage. For instance, the parasitic capacitance in charge holding portion 5 can be increased in an arrangement in which a wire for use in applying a voltage to p-type well region 9 or n-type well region 8 (e.g., well wire 62 connected to diffusion region 59) runs close and parallel to wire 61. Well wire 62 and wire 61 run parallel to each other, for example, in the first direction. However, well wire 62 and wire 61 may run parallel to each other in other direction.

Here, well wire 62 and wire 61 may belong to the same wire layer and be spaced apart from each other in the second direction. Alternatively, well wire 62 and wire 61 may belong to different wire layers and be spaced apart from each other in a third direction intersecting both the first direction and the second direction (that is, the z-axis direction in the figures). It should be noted that an interlayer insulation film is provided between the different wire layers. In addition, well wire 62 may have a layered structure. In this case, it is possible to further increase the parasitic capacitance in charge holding portion 5.

It should be noted that well wire 62 is a wire for use in applying a voltage to p-type well region 9. Apart from well wire 62, there is a well wire (not illustrated) for use in applying a voltage to n-type well region 8. The parasitic capacitance in charge holding portion 5 can be increased also in an arrangement in which such well wires and wire 61 run close and parallel to each other.

### [Variation 1]

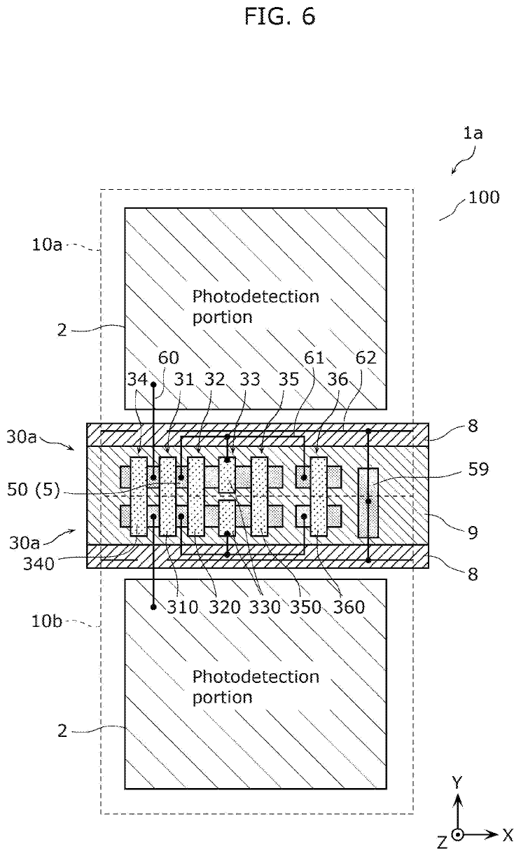

The embodiment described above is just one of various embodiments in the present disclosure. As long as the object of present disclosure is achievable, various changes can be made to the above embodiment in conformity with, for example, a design. For instance, the arrangement of the transistors in pixel circuit 30 is just an example. Hereinafter, a variation (Variation 1) of the arrangement of the transistors is described. FIG. 6 illustrates two pixel cells included in a solid-state image sensor according to Variation 1.

As illustrated in FIG. 6, solid-state image sensor 1a according to Variation 1 includes pixel circuits 30a, and the arrangement of transistors in pixel circuit 30a differs from that of the transistors in a pixel circuit in solid-state image sensor 1. Specifically, in pixel circuit 30a, second reset transistor 34, transfer transistor 31, first reset transistor 32, amplification transistor 33, selection transistor 35, and count transistor 36 are arranged in the order named in the first direction from the left (the negative side of the x-axis).

In such an arrangement, a single region (the same region) serves as diffusion region 58 of amplification transistor 33 and diffusion region 53 of first reset transistor 32. The same diffusion region is connected to, for example, first reset drain electrode 102 (illustrated in FIG. 3). If a single region (the same region) serves as diffusion region 58 of amplification transistor 33 and diffusion region 53 of first reset transistor 32 in this way, it is possible to decrease the length in the first direction, necessary to dispose the transistors, of a region where pixel circuit 30a is disposed. That is, it is possible to miniaturize pixel cell 10. It is no longer possible to cause the power supply voltage of amplification transistor 33 and the reset voltage of photodetection portion 2 to be different voltages simultaneously. However, it is possible to operate pixel circuit 30 by changing the voltage of first reset drain electrode 102 during operation of amplification transistor 33 or adjusting the threshold voltage (Vt) of amplification transistor 33 so that amplification transistor 33 is switched on at the reset voltage of photodetection portion 2.

In addition, in solid-state image sensor 1a, well wire 62 connected to diffusion region 59 and wire 61 connected to charge holding portion 5 (wire 61 may also be considered as a portion of charge holding portion 5) run close and parallel to each other. Such a wire arrangement leads to an increase in the parasitic capacitance in charge holding portion 5, which makes it possible to increase the amount of charge generated when detecting light in the second photodetection mode. It is possible to further increase the parasitic capacitance by causing well wire 62 to have a layered structure or forming well wire 62 in a wire layer above wire 61 included in charge holding portion 5 so that well wire 62 covers wire 61. If well wire 62 is disposed over wire 61, well wire 62 can also be used as a light shielding component for shielding pixel circuit 30a from light illuminated toward pixel circuit 30a.

It should be noted that well wire 62 is a wire for use in applying a voltage to p-type well region 9. In addition to well wire 62, a well wire (not illustrated) for use in applying a voltage to n-type well region 8 may be formed. The parasitic capacitance in charge holding portion 5 can be increased also in a wire arrangement in which such well wires and wire 61 run close and parallel to each other.

### [Variation 2]

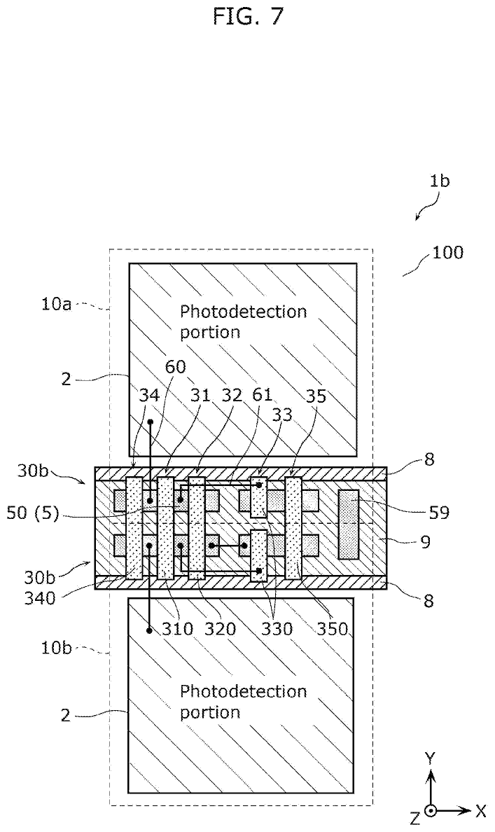

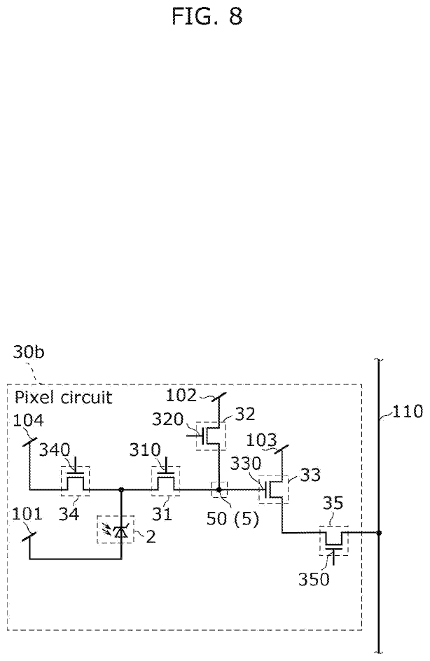

Although pixel circuit 30 and pixel circuit 30a each include six transistors, the number of transistors may be decreased to five or less. FIG. 7 illustrates two pixel cells included in a solid-state image sensor according to Variation 2. FIG. 8 illustrates a circuit configuration of a pixel circuit according to Variation 2.

As illustrated in FIGS. 7 and 8, solid-state image sensor 1b according to Variation 2 includes pixel circuits 30b, and pixel circuit 30b does not include count transistor 36. As illustrated in FIG. 7, in pixel circuit 30b, second reset transistor 34, transfer transistor 31, first reset transistor 32, amplification transistor 33, and selection transistor 35 are arranged in the order named in the first direction from the left (the negative side of the x-axis).

If count transistor 36 is not included, it is possible to decrease the length in the first direction, necessary to dispose the transistors, of a region where pixel circuit 30b is disposed. That is, it is possible to miniaturize pixel cell 10.

It should be noted that if count transistor 36 is not included, it is no longer possible to use the count function in the second photodetection mode. Thus, a photodetection signal output by pixel circuit 30b is a binary signal indicating whether each pixel has detected light.

### [Variation 3]

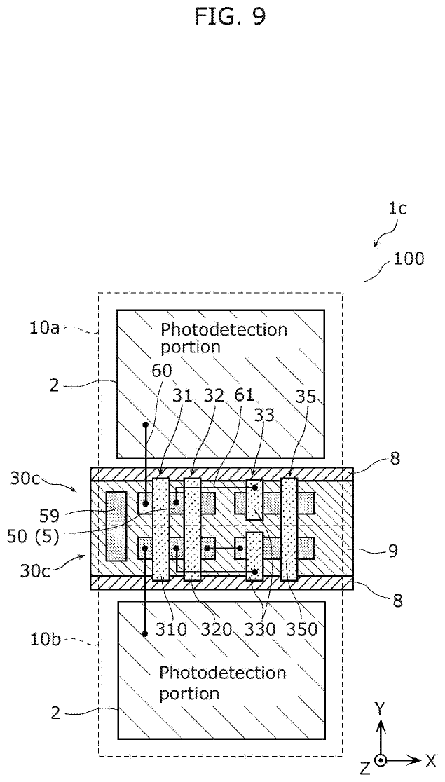

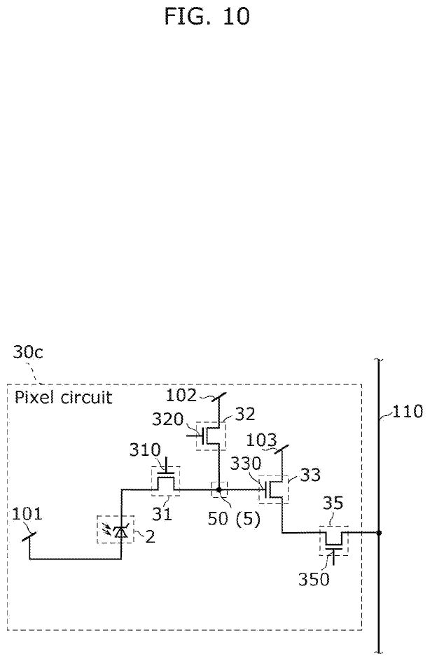

Although pixel circuit 30b includes the five transistors, the number of transistors can be further decreased to four. FIG. 9 illustrates two pixel cells included in a solid-state image sensor according to Variation 3. FIG. 10 illustrates a circuit configuration of a pixel circuit according to Variation 3.

As illustrated in FIGS. 9 and 10, solid-state image sensor 1c according to Variation 3 includes pixel circuits 30c, and pixel circuit 30c does not include second reset transistor 34. As illustrated in FIG. 9, in pixel circuit 30c, transfer transistor 31, first reset transistor 32, amplification transistor 33, and selection transistor 35 are arranged in the order named in the first direction from the left (the negative side of the x-axis).

Thus, if second reset transistor 34 is not included, it is possible to decrease the length in the first direction, necessary to dispose the transistors, of a region where pixel circuit 30c is disposed. That is, it is possible to miniaturize pixel cell 10.

In this case, charge accumulated in photodetection portion 2 is discharged (photodetection portion 2 is reset) by simultaneously switching on transfer transistor 31 and first reset transistor 32. In addition, in pixel circuit 30c, there is a possibility of a portion of charge collected in the cathode of photodetection portion 2 that has exceeded the saturation level overflowing into charge holding portion 5. In such a case, it is possible to suppress the portion of the charge from overflowing into charge holding portion 5 by, for example, setting the threshold voltage (Vt) of transfer transistor 31 to a high voltage, setting a voltage applied when switching off gate electrode 310 of transfer transistor 31 to a low voltage, or disposing diffusion region 59 (a well contact) near diffusion region 52.

### [Outline]

As described above, solid-state image sensor 1 includes semiconductor substrate 100 and pixel cells 10 each of which is formed in and above semiconductor substrate 100 and that are arranged in each of the first direction and the second direction intersecting the first direction to form a two-dimensional array. Pixel cells 10 each include photodetection portion 2 and pixel circuit 30. Photodetection portion 2 receives incident light and generates charge. Pixel circuit 30 includes charge holding portion 5 for holding the charge generated in photodetection portion 2, first transistors arranged in the first direction, and a second transistor that outputs, as a photodetection signal, a voltage corresponding to the charge held by charge holding portion 5. Pixel cells 10 include first pixel cell 10a and second pixel cell 10b arranged in the second direction, and pixel circuit 30 of first pixel cell 10a and pixel circuit 30 of second pixel cell 10b are adjacent to each other in the second direction between a first photodetection portion that is the photodetection portion of first pixel cell 10a and a second photodetection portion that is the photodetection portion of second pixel cell 10b. Each the first transistors of first pixel cell 10a shares a gate electrode with the first transistor of second pixel cell 10b that has the same function as the first transistor of first pixel cell 10a. The second transistor is, for example, amplification transistor 33.

This results in a decrease in the number of connection boundaries between pixel circuits 30 and photodetection portions 2, which can decrease the total area of electric-field-alleviation isolation regions supposed to be disposed on such connection boundaries. Higher sensitivity can be achieved by decreasing the total area of the isolation regions and increasing the area of each photodetection portion 2. In addition, since adjacent pixel cells share the gate electrodes of the first transistors, it is possible to decrease the number and the total area of wires for use in applying voltages to the gate electrodes. Thus, higher sensitivity for incident light having a large incident angle can be achieved by increasing the aperture ratio in a wire region. In addition, it is possible to automatically obtain a target protrusion length that the electrodes of the first transistors protrude from the diffusion regions of the first transistors toward boundary 11. This provides effects in which it is easy to suppress characteristic variations in the threshold voltages (Vt) of the transistors.

In addition, for instance, in plan view, the gate electrode of each of the first transistors of first pixel cell 10a protrudes a first length (first protrusion length A1) from the diffusion regions of the first transistor toward the first photodetection portion. In plan view, the gate electrode of the second transistor of first pixel cell 10a protrudes a second length (second protrusion length A2) from the diffusion regions of the second transistor toward the second photodetection portion. The second length is less than the first length.

Thus, it is possible to decrease parasitic capacitance between charge holding portions 5 by separating gate electrodes 330 of amplification transistors 33 (second transistors) of the two pixel cells from each other by a certain distance. In addition, diffusion regions 50 to 58 can be disposed near boundary 11, which can decrease the width of pixel circuit 30 in the second direction. Thus, higher sensitivity can be achieved by increasing the area ratio of each photodetection portion 2.

In addition, for instance, the first transistors include transfer transistor 31, first reset transistor 32, and selection transistor 35. Transfer transistor 31 transfers charge generated in photodetection portion 2 to charge holding portion 5. First reset transistor 32 resets charge holding portion 5 to discharge the charge accumulated in charge holding portion 5. Selection transistor 35 selects whether a photodetection signal output by the second transistor is output to a signal line.

Thus, pixel circuit 30 including transfer transistor 31, first reset transistor 32, and amplification transistor 33 can generate a photodetection signal corresponding to the light received by photodetection portion 2.

In addition, for instance, the first transistors further include second reset transistor 34 that resets photodetection portion 2 to discharge the charge accumulated in photodetection portion 2.

Thus, when a voltage is applied to gate electrode 340 and second reset transistor 34 is switched on, the charge accumulated in the cathode of photodetection portion 2 can be discharged into second reset drain electrode 104 (the cathode of photodetection portion 2 can be reset). In addition, a portion of the charge accumulated in the cathode of photodetection portion 2 that has exceeded the saturation level overflows into second reset drain electrode 104 across the potential barrier of second reset transistor 34. This can suppress a signal from leaking into charge holding portion 5 during a non-exposure period.

In addition, for instance, pixel circuit 30 further includes memory portion 6, and the first transistors further include count transistor 36 that connects charge holding portion 5 and memory portion 6 to each other.

Thus, it is possible to accumulate, in memory portion 6, the amount of charge corresponding to the number of times light was detected in the second photodetection mode, which leads to an increase in the substantially detectable number of photons. That is, it is possible to increase a dynamic range.

In addition, for instance, each of pixel cells 10 includes p-type well region 9 and well wire 62 for use in applying a voltage to p-type well region 9. Well wire 62 runs parallel to wire 61 connected to charge holding portion 5.

Thus, an increase in the parasitic capacitance in charge holding portion 5 results in an increase in the amount of charge accumulated up to the saturation level of charge holding portion 5 when light is detected. That is, the amount of charge transferable to memory portion 6 increases. Since a voltage change in memory portion 6 per count increases, it is possible to decrease reading errors for the number of counts.

In addition, for instance, well wire 62 and wire 61 that is connected to charge holding portion 5 are formed in the same wire layer.

Thus, it is possible to increase the parasitic capacitance in charge holding portion 5 by disposing well wire 62 and wire 61 close to each other in the same wire layer.

In addition, for instance, well wire 62 and wire 61 that is connected to charge holding portion 5 are formed in different wire layers.

Thus, it is possible to increase the parasitic capacitance in charge holding portion 5 by disposing well wire 62 and wire 61, which are formed in the different wire layers, close to each other.

In addition, for instance, photodetection portion 2 includes a multiplication region where avalanche multiplication of the charge generated by reception of incident light takes place.

Thus, an avalanche photodiode can be used as photodetection portion 2.

In addition, for instance, the arrangement of the first transistors of the first pixel cell in the first direction is identical to that of the first transistors of the second pixel cell in the first direction.

Thus, the shapes of the gate electrodes can be simplified.

In addition, for instance, in plan view, each of the gate electrodes linearly extends in the second direction.

Thus, the shapes of the gate electrodes can be simplified.

In addition, for instance, the second transistor of the first pixel cell does not share a gate electrode with the second transistor of the second pixel cell.

This makes it possible to output a photodetection signal for each pixel cell 10.

In addition, for instance, in pixel circuit 30, the first transistors and the second transistor are arranged in the first direction.

The arrangement of the transistors can be simplified by arranging the transistors of pixel circuit 30 linearly in the first direction.

In addition, for instance, in pixel circuit 30, the second transistor includes two diffusion regions corresponding to the source and drain of the second transistor and shares just one of the two diffusion regions with the first transistors.

By doing so, if for instance diffusion region 58 of the second transistor is isolated from diffusion region 53 of first reset transistor 32 among the first transistors, different power supplies can be connected to these two transistors.

In addition, for instance, in pixel circuit 30a, the second transistor includes two diffusion regions corresponding to the source and drain of the second transistor and shares both of the two diffusion regions with the first transistors.

Thus, if for instance a single region (the same region) serves as both diffusion region 58 of the second transistor and diffusion region 53 of first reset transistor 32 among the first transistors, the size of a region where the transistors are disposed decreases. Thus, pixel cell 10 can be miniaturized.

In addition, for instance, in plan view, the positions of the photodetection portion, the first transistors, and the second transistor in first pixel cell 10a and the positions of the photodetection portion, the first transistors, and the second transistor in second pixel cell 10b are symmetrical to each other with respect to boundary 11 between first pixel cell 10a and second pixel cell 10b.

Thus, the arrangement of the transistors can be simplified.

### Other Embodiment

The solid-state image sensor according to the embodiment is described above. However, the present disclosure is not limited to the above embodiment.

For instance, the arrangement of the transistors described in the above embodiment is a mere example, and the arrangement of the transistors may be changed within the object of the present disclosure. For instance, in a portion of the solid-state image sensor, an arrangement different from an arrangement in the other portions may be employed.

In addition, in the above embodiment, the controller of the solid-state image sensor operates the pixel cells in the two photodetection modes, the first and the second photodetection modes. However, the controller does not have to operate the pixel cells in the first photodetection mode and may operate the pixel cells only in the second photodetection mode.

In addition, in the above embodiment, the conductivity types of diffusion regions 51 to 58, which are the diffusion regions other than the well contact (diffusion region 59), may be p-type. The conductivity type of the well contact (diffusion region 59) may be n-type. P-type well region 9 may be an n-type well region. In this case, there is no boundary between p-type well region 9 and n-type well region 8, which enables miniaturization of the pixel cells.

In addition, in the above embodiment, the well contacts are disposed, one for each of the pixel cells to make the p-type well regions of the pixel cells have a uniform voltage. However, the well contacts do not have to be disposed, one for each of the pixel cells. The well contacts may be disposed, one for two or more pixel cells, or one or two well contacts may be disposed for pixel cells for one row. If the number of well contacts is decreased, the pixel cells can be miniaturized.

In addition, in the above embodiment, the first direction is orthogonal to the second direction. However, the angle formed by the first direction and the second direction may be less than 90 degrees. In this case, the positions of the transistors in the first pixel cell and the positions of the transistors in the second pixel cell may not be symmetrical to each other with respect to a horizontal line. However, the order in which the transistors are arranged is the same in the first pixel cell and the second pixel cell.

In addition, all the numbers used in the explanations in the above embodiment are provided for exemplification purposes to describe the present disclosure in detail. Numbers in the present disclosure are not limited to the numbers described in the above embodiment.

In addition, the circuit configuration described in the above embodiment is a mere example, and the circuit configurations in the present disclosure are not limited to the circuit configuration described above. That is, the present disclosure includes a circuit capable of achieving the characteristic functions of the present disclosure in the same way as the circuit configuration described above. For instance, as long as functions similar to the functions achieved in the circuit configuration described above are achievable, the present disclosure also includes a configuration in which an element, such as a switching element (transistor), a resistance element, or a capacitance element, is connected in parallel or in series to an element.

In addition, in the embodiment, the main materials of the structural elements of the solid-state image sensor are exemplified. However, as long as functions similar to the functions of the layered structure(s) described in the above embodiment are achievable, each layer of the layered structure(s) of the solid-state image sensor may include other materials. In addition, in the drawings, corners and sides of each structural element are drawn in straight lines. However, the present disclosure also includes round corners and curved lines created for manufacturing or other reasons.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure. The present disclosure also includes one or more embodiments obtained by making various changes envisioned by those skilled in the art to the embodiments or one or more embodiments obtained by optionally combining the structural elements and functions described in the embodiments without departing from the scope of the present disclosure. For instance, the present disclosure may be embodied as a method of manufacturing a solid-state image sensor.

### INDUSTRIAL APPLICABILITY

The solid-state image sensors in the present disclosure are useful as solid-state image sensors suitable to achieve higher sensitivity.

1. A solid-state image sensor comprising:
a semiconductor substrate; and
a plurality of pixel cells each of which is formed in and above the semiconductor substrate and that are arranged in each of a first direction and a second direction intersecting the first direction to form a two-dimensional array,
wherein the plurality of pixel cells each include:
a photodetection portion for receiving incident light and generating charge; and
a pixel circuit including:
a charge holding portion for holding the charge generated in the photodetection portion;
a plurality of first transistors arranged in the first direction; and
a second transistor that outputs, as a photodetection signal, a voltage corresponding to the charge held by the charge holding portion,
the plurality of pixel cells include a first pixel cell and a second pixel cell arranged in the second direction, and the pixel circuit of the first pixel cell and the pixel circuit of the second pixel cell are adjacent to each other in the second direction between a first photodetection portion that is the photodetection portion of the first pixel cell and a second photodetection portion that is the photodetection portion of the second pixel cell, and
each of the plurality of first transistors of the first pixel cell shares a gate electrode with a corresponding one of the plurality of first transistors of the second pixel cell that has a same function as the first transistor of the first pixel cell.

2. The solid-state image sensor according to claim 1,
wherein in plan view, the gate electrode of each of the plurality of first transistors included in the first pixel cell protrudes a first length from a diffusion region of the first transistor toward the first photodetection portion,
in plan view, a gate electrode of the second transistor of the first pixel cell protrudes a second length from a diffusion region of the second transistor toward the second photodetection portion, and
the second length is less than the first length.

3. The solid-state image sensor according to claim 1,
wherein the plurality of first transistors include:
a transfer transistor that transfers the charge generated in the photodetection portion to the charge holding portion;
a first reset transistor that resets the charge holding portion to discharge the charge accumulated in the charge holding portion; and
a selection transistor that selects whether the photodetection signal output by the second transistor is output to a signal line.

4. The solid-state image sensor according to claim 3,
wherein the plurality of first transistors further include a second reset transistor that resets the photodetection portion to discharge the charge accumulated in the photodetection portion.

5. The solid-state image sensor according to claim 4,
wherein the pixel circuit further includes a memory portion, and
the plurality of first transistors further include a count transistor that connects the charge holding portion and the memory portion to each other.

6. The solid-state image sensor according to claim 1,
wherein each of the plurality of pixel cells includes a well region and a well wire for use in applying a voltage to the well region, and
the well wire runs parallel to a wire connected to the charge holding portion.

7. The solid-state image sensor according to claim 6,
wherein the well wire and the wire connected to the charge holding portion are formed in an identical wire layer.

8. The solid-state image sensor according to claim 6,
wherein the well wire and the wire connected to the charge holding portion are formed in different wire layers.

9. The solid-state image sensor according to claim 1,
wherein the photodetection portion includes a multiplication region where avalanche multiplication of the charge generated by reception of the incident light takes place.

10. The solid-state image sensor according to claim 1,
wherein an arrangement of the plurality of first transistors of the first pixel cell in the first direction is identical to an arrangement of the plurality of first transistors of the second pixel cell in the first direction.

11. The solid-state image sensor according to claim 1,
wherein in plan view, the gate electrode of each of the plurality of first transistors linearly extends in the second direction.

12. The solid-state image sensor according to claim 1,
wherein the second transistor of the first pixel cell does not share a gate electrode with the second transistor of the second pixel cell.

13. The solid-state image sensor according to claim 1,
wherein in the pixel circuit, the plurality of first transistors and the second transistor are arranged in the first direction.

14. The solid-state image sensor according to claim 1,
wherein the second transistor includes two diffusion regions corresponding to a source and a drain of the second transistor and shares just one of the two diffusion regions with the plurality of first transistors.

15. The solid-state image sensor according to claim 1,
wherein the second transistor includes two diffusion regions corresponding to a source and a drain of the second transistor and shares both of the two diffusion regions with the plurality of first transistors.

16. The solid-state image sensor according to claim 1,
wherein in plan view, positions of the photodetection portion, the plurality of first transistors, and the second transistor in the first pixel and positions of the photodetection portion, the plurality of first transistors, and the second transistor in the second pixel cell are symmetrical to each other with respect to a boundary between the first pixel cell and the second pixel cell.
